(19) United States
(12) Patent Application Publication
(10) Pub. No.: US 2005/0018719 A1
(43) Pub. Date: Jan. 27, 2005

(54) Tuneable laser with improved suppression of auger recombination

(76) Inventors: Nick Zakhleniuk, Colchester (GB); Andrew Cannon Carter, Northampton (GB); Anthony Holden, Brackley (GB); David James Robbins, Towcester (GB)

Correspondence Address: LAHIVE & COCKFIELD, LLP., 28 STATE STREET, BOSTON, MA, 02109, US

(21) Appl. No.: 10/492,430

(22) PCT Filed: Oct. 10, 2002
(86) PCT No.: PCT/GB02/04595

(30) Foreign Application Priority Data
Oct. 11, 2001 (GB) 0124357.5

(51) Int. Cl. H01S 3/10; H01S 5/00

(52) U.S. Cl. 372/20; 372/43; 372/44

(57) ABSTRACT

A junction region for the laser diode may be improved to give an increased wavelength tuning range with improved thermal stability. The region has a homojunction structure that modifies the band structure to approximate that found in a type II superlattice. Up to half of the InGaAsP layer that nearest the p-InP region is n-type doped leaving the remainder with the original doping profile. This creates separate potential wells for electrons and holes in different parts of the InGaAsP layer. Also the barrier for electrons, but not for the holes, on the (p-InP)-(I-InGaAsP)-heterojunction may be increased by inserting a blocking layer of InAlAs, which is lattice matched to InP and InGaAsP, on the p-side between the above two materials.

The present invention relates to a tuneable laser. More particularly, but not exclusively, it relates to a laser junction region having an increased electron barrier and/or a reduced Auger recombination rate.

Narrow band lasers are important for a number of applications in optical telecommunications and signal processing applications. These include multiple channel optical telecommunications networks using wavelength division multiplexing (WDM). Such networks can provide advanced features, such as wavelength routing, wavelength conversion, adding and dropping of channels and wavelength manipulation in much the same way as in time slot manipulation in time division multiplexed systems. Many of these systems operate in the C-band in the range 1530 to 1570 nm.

Tuneable lasers for use in such optical communications systems, particularly in connection with the WDM telecommunication systems, are known. A known tuneable system comprises stacks of individually wavelength distributed Bragg reflectors (DBR) lasers, which can be individually selected, or by a wide tuning range tuneable laser that can be electronically driven to provide the wavelength required. Due to the crucial importance of the tuning process for the application of laser diodes in optical telecommunications and optical interconnects there is active and sustained interest in developing new tuning mechanisms and optimising existing ones. The invention in this patent addresses the latter point.

In monolithic semiconductor diode lasers such wavelength tuning can be achieved by a number of methods that utilise different physical properties of the materials used in the construction of the lasers.

Wavelength tuning may be accomplished in several ways.

Firstly, there is the free carrier plasma effect, in which the electronic dielectric function dispersion ε(ω) is dependent on the free carrier density no and this is used to modify the optical properties of the medium

$$ɛ ( ω ) = {ɛ}_{∞} ( 1 - \frac{{ω}_{p}^{2}}{{ω}^{2}} ) ,$$

Where

$${ω}_{p} = {( \frac{{n}_{0} {e}^{2}}{{ɛ}_{0} {ɛ}_{∞} {m}^{*}} )}^{\frac{1}{2}}$$

is a plasma frequency.
ε_{∞} is the high-frequency lattice dielectric constant
m^{*} is the electron effective mass
ε₀ is the vacuum permittivity

A change in the electron density n, from the injection of free carriers causes a change in the plasma frequency q. This leads to a change in the refractive index n (ω) of the material since n² (ω)=ε(ω). An increase in the electron density results in a decrease in the refractive index of the material.

The advantages of this tuning mechanism are it's relatively high tuning speed, up to approximately 1 GHz, the large wavelength tuning range and the ability to realise continuous tuning. The drawback of the mechanism is that the injected electron-hole pairs subsequently recombine and this requires a sustained current that leads to heat generation in the device.

Secondly, there is the quantum confined Stark effect (QCS), which may be utilised with quantum well structures. The Franz-Keldysh effect is exploited in the multiple quantum well heterostructure with the electric field applied normal to the quantum well interfaces. The electric field induces a change in the energy differences between the electron and hole ground states in the quantum well and also displaces the centres of the electron and hole wavefunctions with respect to each other. As a consequence the electron-hole transition matrix element is reduced and the electronic refractive index changes.

The refractive index change due to the QCS effect is negative, similar to the change caused by any free electron plasma effect. It should be noted that unlike bulk materials, the interaction of light with charge carriers near the bandgap is primarily due to excitonic effects rather than free carriers in the quantum well structures.

At wavelengths close to excitonic resonance the refractive index changes in the quantum well heterostructure are two orders of magnitude larger than in bulk material. In III-V semiconductors the refractive index change is typically of the order of 10⁻³ to 10⁻².

The advantages of this tuning mechanism are firstly the high tuning speed, there are practically no internal time constants and the speed is limited only by external parasitic elements and secondly there is negligible heat generation. However the tuning range realised by this scheme is considerably smaller than that achieved with the free electron plasma effect and the effect is temperature sensitive.

However, practical realisation of the scheme is technically demanding since the maximum change in the refractive index takes place at wavelengths close to the exciton resonance where absorption is also large.

Finally, there is thermal tuning, in which the bandgap of a material and its Fermi distribution parameters depend on the ambient temperature. Consequently temperature can be used as a means to vary the emission wavelength and refractive index of the laser medium. A point to note is that unlike the previous two effects, where the changes in the refractive index were negative, increasing the temperature will decrease the bandgap and increase the refractive index.

The advantages of the thermal tuning scheme are the relative simplicity and relatively large tuning range. The disadvantages are the very large heat generation in the devices and the very low tuning speed. Tuning requires either the heating or cooling of the laser chip and such processes do have large time constants.

Of the three mechanisms described above the free electron plasma effect is most commonly used in monolithic, continuously tuneable semiconductor laser diodes. In order to tune the emission wavelength, free carriers are injected via electrodes into the tuning region of the laser. As stated earlier increasing the electron density will reduce the refractive index of the material

In general, two effects limit the maximum tuning range:
(i) The rise in the device temperature due to current heating results in a positive shift in wavelength that acts in opposition to the shift caused by the free carrier plasma effect.
(ii) At high hole densities the optical losses due to inter-valence band absorption increase, thus the optical output power decreases with increasing tuning current.

Therefore the optimal operation regime of the tuning section of the laser will occur when the maximum free electron density nₒ is achieved for a minimum injection current I.

The tuning efficiency due to carrier injection decreases at high carrier densities because of non-linear recombination mechanisms. The main recombination process is Auger recombination.

The tuning current is given by:
I=eV(C₁nₒ²p₀+C₂nₒpₒ²)
where:
   nₒ is the electron density
   pₒ is the hole density
   C₁ & C₂ are the Auger recombination coefficients
   V is the volume of the tuning region

In the normal operation of the laser diode there is a high injection current and low doping in the tuning region of the laser and thus the following approximations can be made nₒ≈pₒ and so I=eVCnₒ³.

From the above expression it can be seen that for a given electron and hole densities nₒ & pₒ the minimum current can be achieved by either (a) decreasing the volume V of the tuning section, or (b) decreasing the Auger coefficients.

The volume V of the tuning section is however predetermined by the design of the tuning section, normally the size of the sampled grating design, and by the dimensions of the laser's active gain section.

The Auger recombination coefficient is a material property. It could be decreased in theory by choosing a material for the tuning section with a large bandgap energy or one which has indirect conduction—valence bands. However integration of the active gain and tuning section on the same laser chip impose design constraints on the choice of materials which make this unfeasible.

The solution is to suppress the Auger recombination rate by creating inhomogeneous electron and hole distribution profiles n(\vec{r}) and p(\vec{r}) in the tuning region in such a manner that the electron and hole densities remain high but the overlap between the electron and hole profiles is small i.e. the products n²(\vec{r})p(\vec{r}) and n(\vec{r})p²(\vec{r}) are minimal in the tuning region.

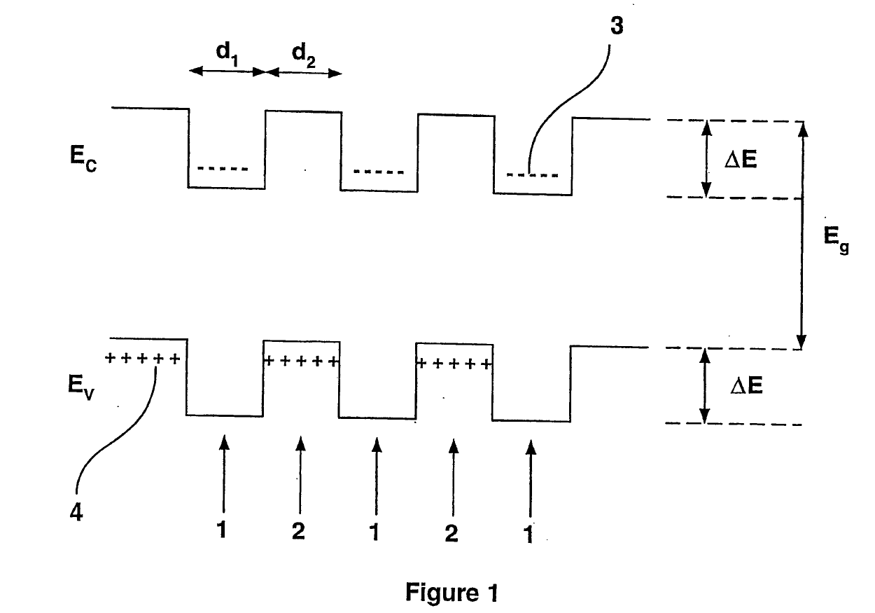

It is known in the art that the incorporation of a type II superlattice into the tuning region is a means to decrease the effective Auger recombination rate. In such a heterostructure the electrons and holes are spatially separated as shown in FIG. 1. In the type UI superlattices the sign of the energy and discontinuity at each interface is the same for the conduction bands and for the valence bands. As a result of this in each separate layer there exists a potential quantum well for electrons (holes) and a potential barrier for holes (electrons). The situation is different in type I superlattices where in one layer there is a quantum well for electrons and holes while in an adjacent layer there is a barrier for both types of carriers.

In FIG. 1 the bandgap energy of materials in layers 1 and 2 is chosen to be constant. The electrons are confined in layer 1, while the holes are confined in layer 2. This separation, of course, is not complete since due to finite height of the barriers the electron and hole wave functions penetrate into the adjacent barriers. Also, due to thermal excitation there is a number of electrons above the barrier in layers II and there is a number of holes above the barrier in layers L Nevertheless, it is assumed that the majority of electrons will be in layers I and majority of the holes will be in layers II. As a result of this the products of the electron and hole densities n_{I(II)} and p_{I(II)} in each layer are small: n_{I(II)}²p_{I(II)}<<n₀³ and n_{I(II)}p_{I(II)}²<<n₀³. This will suppress an average Auger recombination rate and reduce the current consumption in the tuning region with incorporated superlattice in comparison with the case of bulk tuning region.

Semiconductor materials for the tuning region with a bandgap wavelength of 1.3 μm being lattice matched to InP have been studied by S. Neber and M-C Amann, “Tuneable laser diodes with type II superlattice in the tuning region”, Semicond. Sci. Technol. 13 801-805 (1998). All quaternary combinations of Al, Ga, In, As, Sb, and P were taken into account. As a result InGaAsP, AlGaInAs, and AlGaAsSb were identified as suitable semiconductors. The results for these materials are given in Table 1 and Table 2:

TABLE 1

| | Δa/a | | | Ec | Eᵥ^{lh} | Eᵥ^{hh} | Eg |
|---|---|---|---|---|---|---|---|
| Material | (%) | x | y | (eV) | (eV) | (eV) | (eV) |
| InP | 0 | | | −5.649 | −7.003 | | 1.354 |
| AlₓIn₁₋ₓAs | 0 | 0.475 | | −5.465 | −6.880 | | 1.415 |
| GaₓIn₁₋ₓP_{y}As_{1-y} | 0 | 0.328 | 0.202 | −5.808 | 6.758 | | 0.950 |
| GaₓIn₁₋ₓP_{y}As_{1-y} | 1, compressive | 0.051 | 0.576 | −5.845 | −6.851 | −6.795 | 0.950 |
| GaₓIn₁₋ₓP_{y}As_{1-y} | 1, tensile | 0.546 | 11,215 | −5.768 | −6.718 | −6.794 | 0.950 |

| | | | | | | |
|---|---|---|---|---|---|---|
| AlₓGa₁₋ₓAs_{y}Sb_{1-y} | 0 | 0.075 | 0.516 | −5.506 | −6.456 | 0.950 |
| AlₓGa₁₋ₓAs_{y}Sb_{1-y} | 0 | 0.119 | 0.519 | −5.443 | −6.476 | 1.033 |
| AlₓGa₁₋ₓIn_{1-x-y}As | 0 | 0.151 | 0.310 | −5.784 | −6.734 | 0.950 |

TABLE 2

| Material 1 | GaInPAs | GaInPAs | AlGaAsSb |
|---|---|---|---|
| Material 2 | AlGaAsSb | AlGaInAs | AlGaInAs |
| Band off set (meV) | 302 | 24 | 278 |

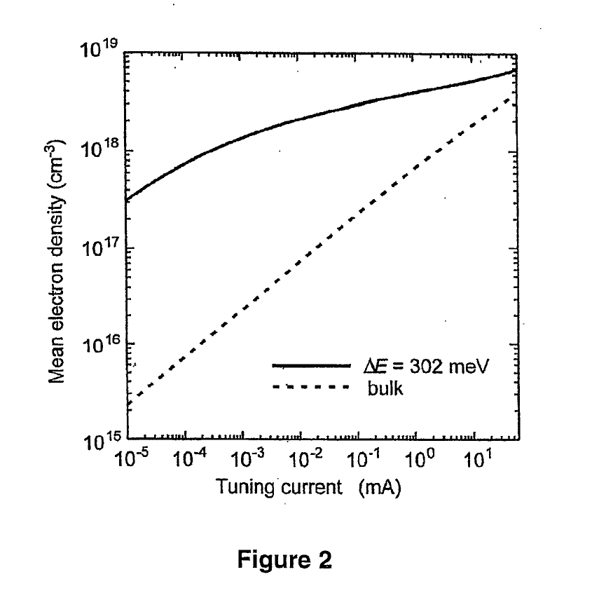

The combination GaInAsP/AlGaAsSb is most suitable for the necessary realisation as it offers the largest band offsets. The obtained result is shown in FIG. 2 where the mean electron density as a function of tuning current for a type II superlattice with ΔE=302 meV, a constant bandgap wavelength of 1.3 μm and equal layer thicknesses d₁=d₂.

For comparison the case of the bulk tuning region is also shown in FIG. 2. In order to obtain a consistent result at a small current, the equation for current has been modified by including the terms which describe the contribution of the Shockley-Read-Hall recombination (∝An) and radiative band to band recombination (∝Bn²). The mean electron density was obtained by integration over one period of the superlattice and dividing by (d₁+d₂). The mean electron density and the mean hole density are assumed to be equal in order to maintain overall charge neutrality.

The calculations showed significant increases in mean electron density. Even at high tuning current the mean electron density is enhanced by a factor of about 3 in comparison with the bulk tuning region. At small currents the improvement factor is about 150.

However, in practise the improvements would not be as significant, since all superlattice layers cannot be considered as bulk materials with different properties. The thickness of the tuning section is in reality about 300-400 nm and an incorporation of 5-6 periods of the superlattice will result in the thickness of each layer being about 30 nm.

In this case the layers will be well connected with each other due to quantum overlap of the wavefunctions in neighbouring layers (especially taking into account that the barriers are not very high, only about 0.3 eV). Also, due to the 2D quantisation of the energy levels in each layer, the effective barrier height will be smaller than the bands offset. Therefore, a bulk-like interpretation of the layers may overestimate the spatial separation of the electrons and holes.

Also the conduction and valence band profiles as shown in FIG. 1 contain a flat band approximation. In reality the bands will be bent which will decrease the actual barrier height.

Furthermore an external electric field will modify the band profiles. The tuning section is in fact a p-i-n diode and the external bias will drop mainly in the undoped i-region. In this case the potential profile shown in FIG. 1 will be transformed.

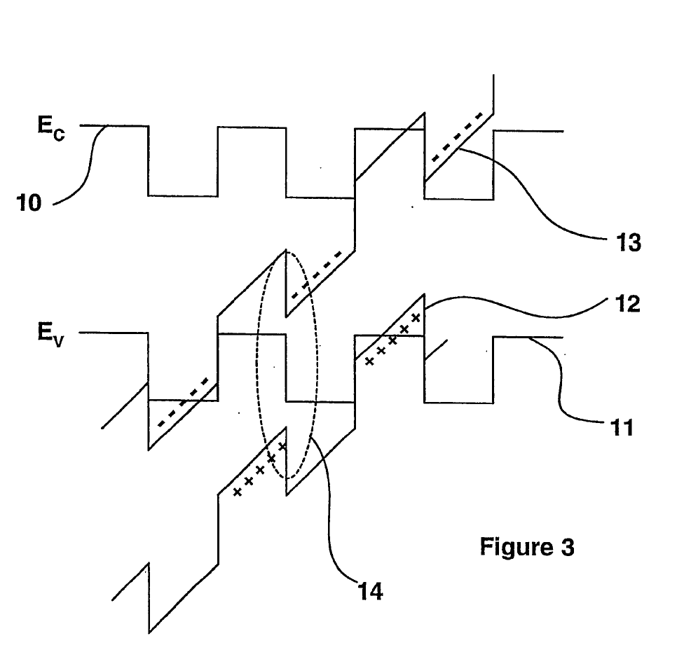

A schematic profile in the presence of electric field is shown in FIG. 3, from which it can be seen that, due to conduction and valence band inclination, the electrons and the holes in adjacent layers come closer together than in the case of zero electric field, as indicated by the dashed oval line 14 in FIG. 3. This will increase the recombination rate and thus will decrease the average electron density in the tuning section.

Incorporation of type II superlattice is essentially equivalent to the creation of an artificial semiconductor with indirect conduction and valence bands and the materials forming the superlattice may well not be ideally matched to the other materials used in the construction of the laser. As stated above, the GaInAsP/AlGaAsSb combination theoretically gives the largest band offset and hence reduction in Auger recombination. However such a material system is not necessarily compatible with a number of material systems used in the manufacture of laser diodes.

Another factor that needs to be considered is the location at which carrier recombination actually occurs. To achieve maximum tuning the aim is to achieve maximum carrier density in the tuning section for a given injection current. As stated above this may be done by suppressing the Auger recombination in the tuning section, assuming that all the injected carriers, both electrons and holes, will subsequently recombine there.

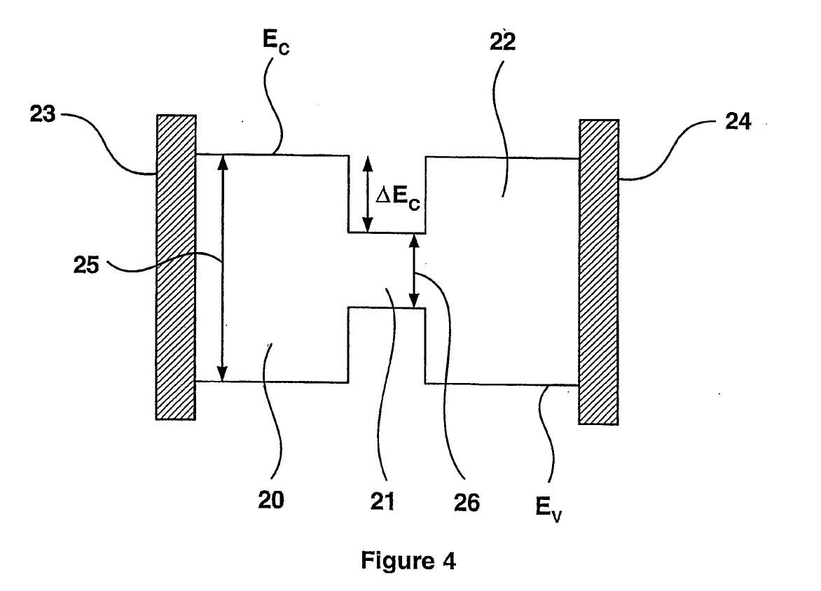

However consideration of the tuning section of a InP/InGaAsP/InP p-i-n diode laser, as shown in FIG. 4, shows that there are device structure constraints on the efficiency of such recombinations. FIG. 4 shows the band structure of the tuning region of such a laser with an IaP p-type region 20, an InGaAsP intrinsic un-doped region 21 and an InP n-type region 22. At either side of the section are ohmic contacts 23 and 24. Marked are the positions of the conduction band E_{C} and the valence band E_{V}. Also shown is the difference in energy in the conduction band between the intrinsic un-doped region and the doped regions, ΔE_{C} and the bandgaps for the InP and InGaAsP regions marked as 25 and 26 respectively.

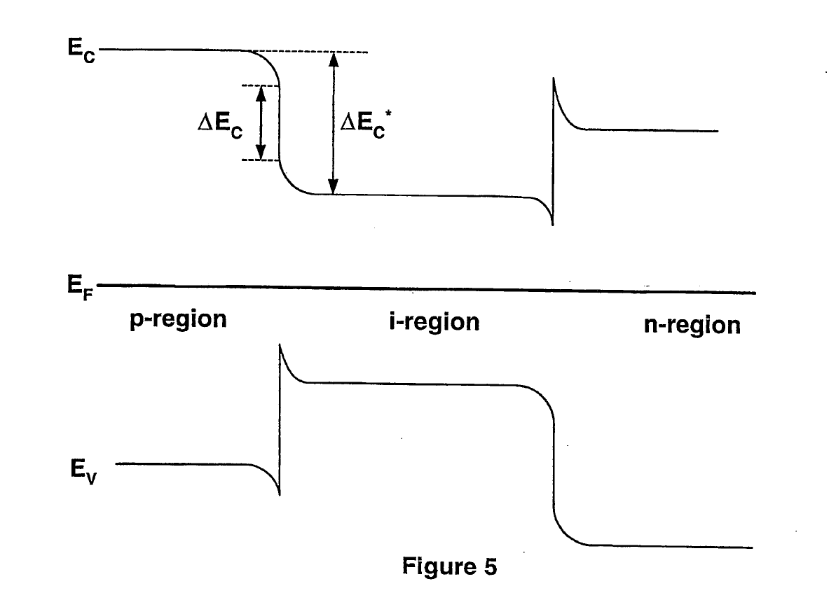

FIG. 5 shows a schematic potential energy profile of the tuning region of a laser diode that incorporates the effect of band-bending. Band-bending occurs due to the requirement that the quasi-Fermi level should be constant throughout the whole of the structure. As can be seen from FIG. 5 the barrier height seen by electrons in the i-region, ΔE_{C}*, is increased compared to ΔE_{C} when the effects of band bending is accounted for.

Only carriers injected into the undoped i-region 21 will contribute to the change in refractive index and not all of the injected carriers will recombine in the undoped region. This is because the leakage current may take a considerable fraction of the injected carriers away from the tuning region. The total leakage current is the sum of the electron current in the p-region 20 and the hole current in the n-region 22 of the p-i-n heterostructure. As a result of this leakage current the effective number of carriers available for recombination in the i-region is decreased resulting in a lower tuning efficiency.

The leakage current is relatively large because the heterojunction barrier height, ΔE_{C}, for electrons is relatively small. Assuming a wavelength of λ=1.42 μm and that the ratio for the conduction band/valence band offset is 40/60 then the resulting band gaps are E_{g}^{InP}=1.35 eV (25) and E_{g}^{InGaAsP}=0.873 eV (26). This gives ΔE_{C}=0.191 eV and ΔEᵥ=0.286 eV.

Another factor to consider is the effect of the small electron effective mass in the InGaAsP. In this region mₙ^{*}=0.05 m₀ and this results in a small density of states in the i-region. Thus for typical injected electron densities n₀≈2-3×10¹⁸ cm⁻³ the Fermi energy E_{F}=0.15 eV. Thus the Fermi energy Ep of the injected electron gas in the i-region is comparable to the above barrier height resulting in an effective barrier height of less than 50 meV. This will result in a relatively large electron leakage current. The hole leakage current will be considerably smaller due to the hole effective mass being an order of magnitude larger than the electron effective mass which results in a smaller Fermi energy and the higher potential barrier for holes.

Thus the maximum tuning efficiency will be achieved by decreasing the electron leakage current over the heterojunction from the i-region and suppressing the Auger recombination in the i-region. The present invention addresses these problems and provides a device structure that provides a solution to carrier localisation and reduction in non-radiative recombinations.

It is an object of the present invention to provide a heterojunction structure that provides firstly a means for the spatial localisation of the different carrier types and hence a reduction of non-radiative Auger recombination, and secondly a means of electron leakage current reduction.

According to a first aspect of the present invention, there is provided the tuning section of a tuneable laser incorporating a novel homojunction structure that modifies the band structure to approximate that found in a type II superlattice.

The tuning section of the tuneable laser may be a (p-InP)-(i-InGaAsP)-(n-InP) structure, wherein up to half of the InGaAsP layer is doped leaving the remainder in the original intrinsic state, so as to create separate potential wells for electrons and holes in different parts of the InGaAsP layer.

Preferably the region of the i-InGaAsP nearest the p-InP is n-type doped, with the remainder of the region being undoped. In this case there is a potential well for electrons in the n-doped region of th InGaAsP layer and a potential well for holes in the undoped region of this layer.

Alternatively the region of the i-InGaAsP nearest the p-InP is n-type doped, with the remainder of the region being p-doped. In this case there is an enhanced potential well for electrons in the n-doped region of the InGaAsP layer and an enhanced potential well for holes in the undoped region of this layer.

According to a second aspect of the invention, there is provided the tuning section of a tuneable laser incorporating a hetrojuction structure comprising a blocking layer between the two materials thereof on the pAside so as to increase the barrier for electrons only, but not for holes, while maintaining the same injection level for the electron and hole current.

The material of the blocking layer has to be latticed matched to the adjacent layers. The blocking material may be InAlAs or InAlAsP for the case of a tuning section of the tuneable laser having a (p-InP)-(i-InGaAsP)-(n-lnP) structure.

Preferably, insertion of the blocking layer provides an additional barrier for the electrons of about 0.2 eV and substantially no additional barrier for the holes.

According to a third aspect of the present invention, there is provided a tuneable laser comprising in combination any feature of the first aspect described above and any feature of the second aspect described above.

Embodiments of the present invention will now be more particularly described by way of example and with reference to the accompanying drawings, in which:

FIG. 1 shows schematically a known tuning region including a type II superlattice giving a heterostructure in which electrons and holes are spatially separated;

FIG. 2 shows graphically the mean electron density as a function of tuning current for a type II super lattice with ΔB=302 meV;

FIG. 3 is a schematic profile of the prior art tuning region in the presence of electric field;

FIG. 4 shows the tuning section of a known InP/InGaAsP/InP p-i-n diode laser;

FIG. 5 shows a schematic potential energy profile of the tuning region of a laser diode incorporating the effect of band-bending;

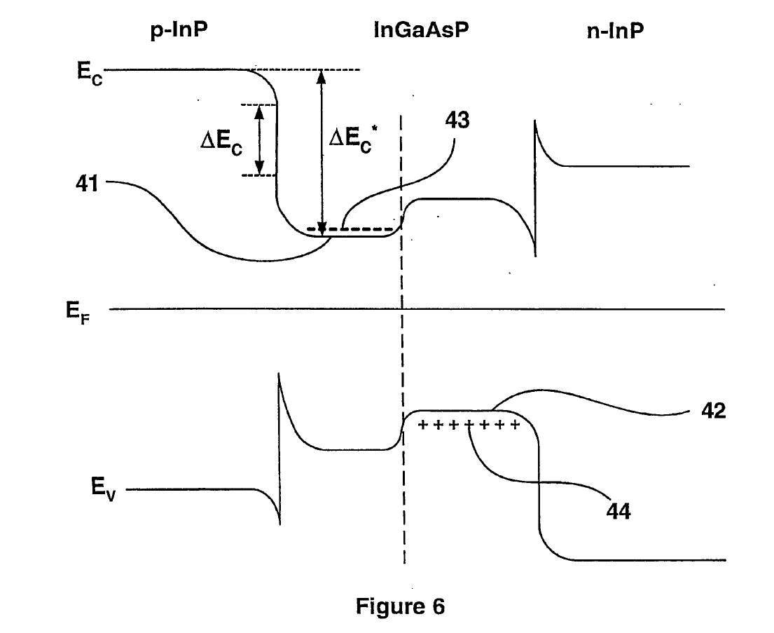

FIG. 6 shows the resulting band structure when the region of the i-InGaAsP nearest the p-InP region is n-type doped, leaving the remainder undoped;

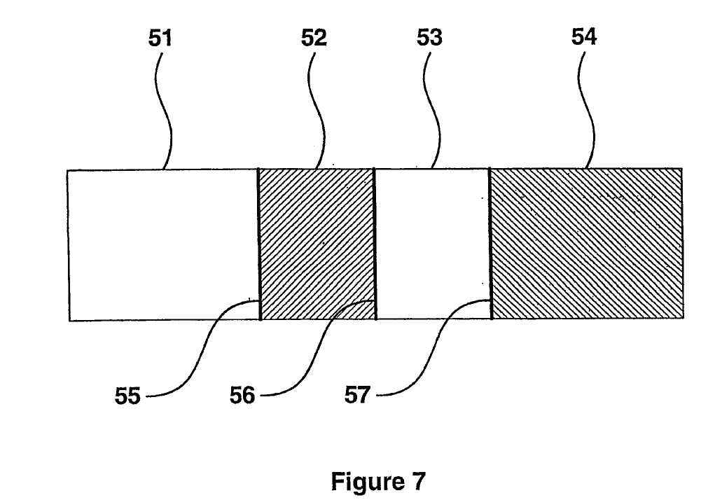

FIG. 7 shows schematically a structure having a p-In region, an n-doped InGaAsP region, an intrinsically doped InGaAsP (i-InGaAsP) region, and an n-doped InP region;

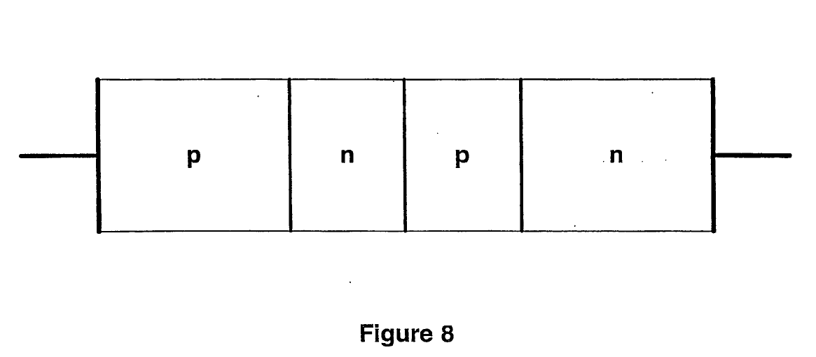

FIG. 8 shows a two terminal p-n-p-n Shockley diode;

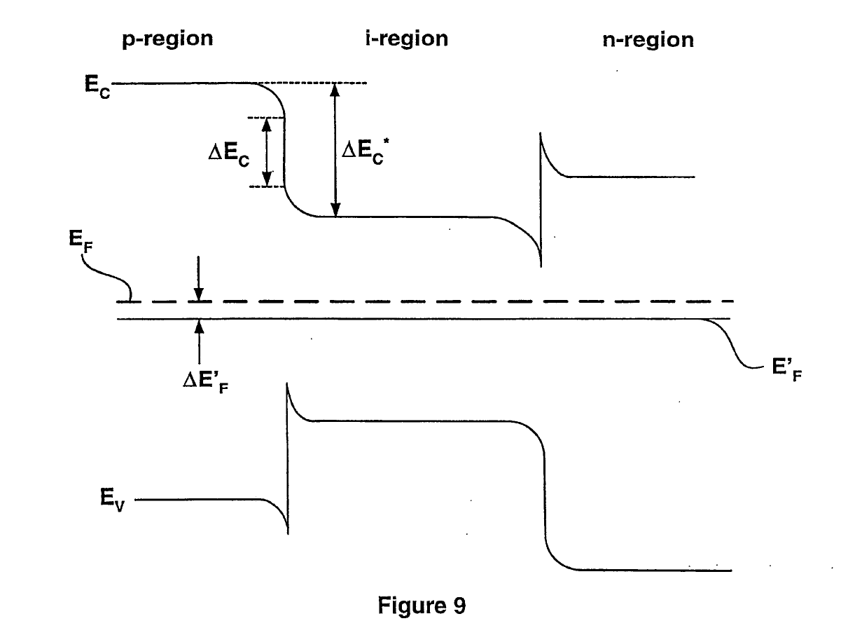

FIG. 9 shows a schematic potential energy profile as shown in FIG. 5, with an additional Fermi level shift;

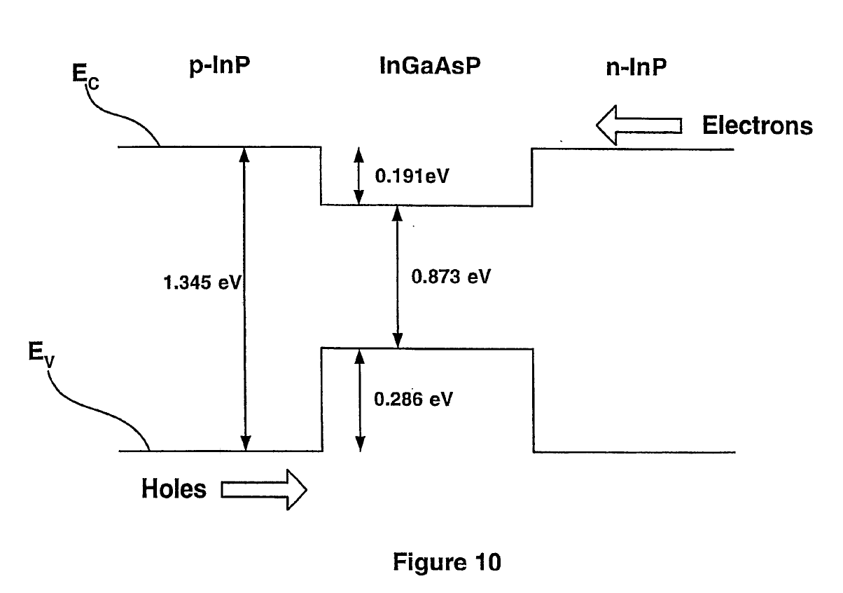

FIG. 10 shows the energy band profile of the structure before incorporation of a blocking layer;

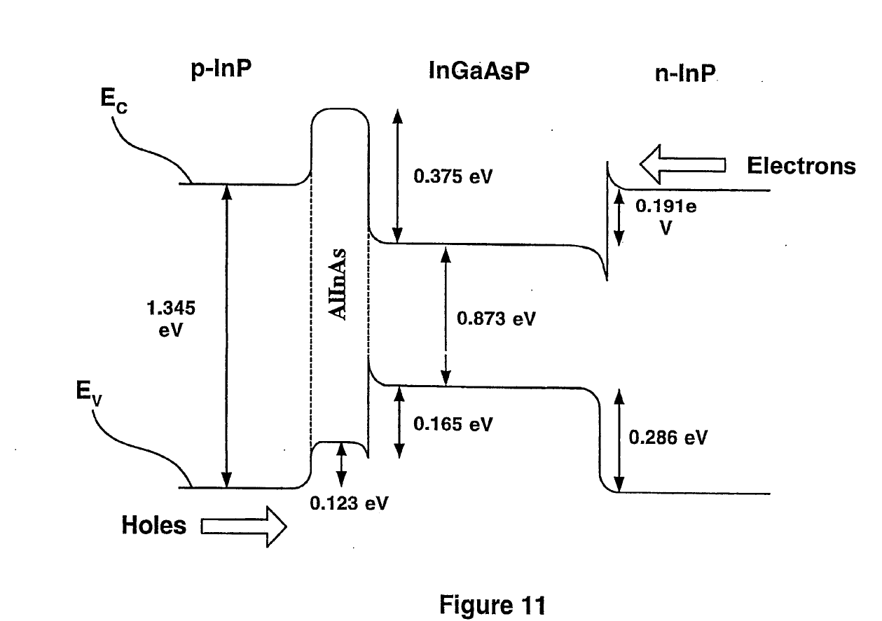

FIG. 11 shows the energy band profile of the structure of FIG. 10 when an InAlAs blocking layer is inserted;

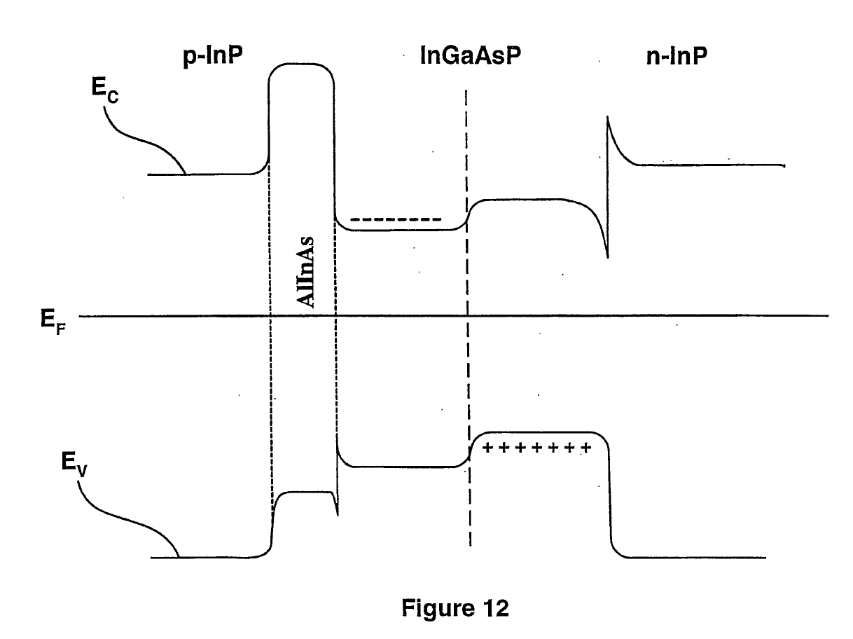

FIG. 12 shows the resulting band structure when the two aspects of the invention are combined;

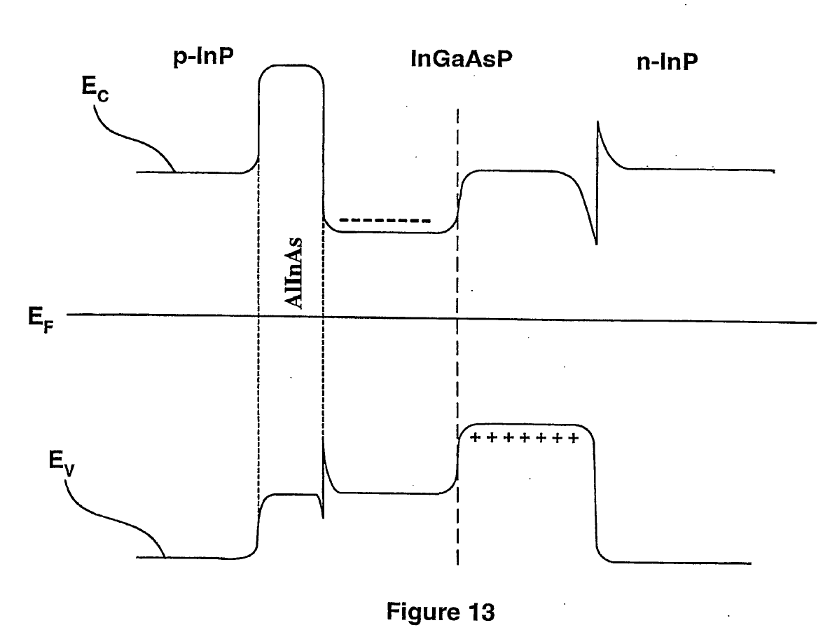

FIG. 13 shows the band structure of FIG. 12 with the remaining part of the i-region being p-doped;

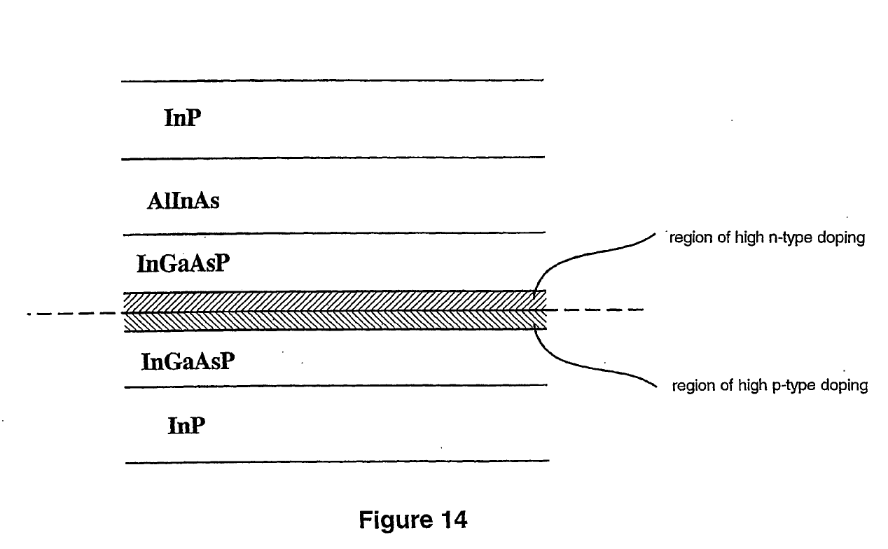

FIG. 14 shows the physical layer structure of a tuning region of a laser diode which incorporated delta doping; and

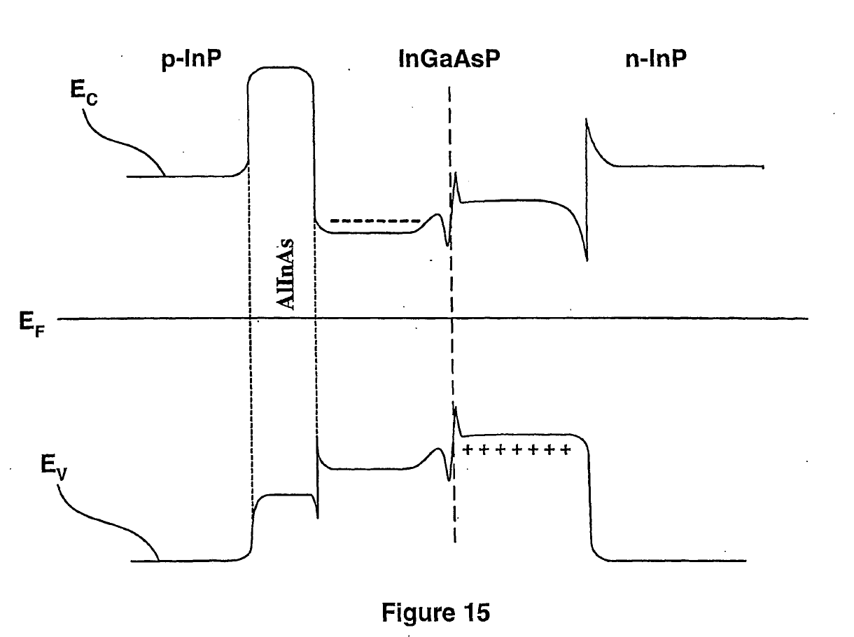

FIG. 15 shows the band structure of a tuning region of a laser diode which incorporated delta doping.

To achieve maximum tuning at minimum possible injection current it is necessary to reduce the amount of Auger recombination that takes place in the tuning region. It is known that the only method of reducing the Auger recombination rate that is technically achievable within a tuning section where there are constraints on the material systems used is the physical separation of the electrons and holes. This may be accomplished by modulating the doping profile within the i-region to separate spatially the carriers, with the resulting structure approximating that of a type II superlattice, resulting in an enhanced carrier density in the i-region.

Separation between electrons and holes in the i-InGaAsP layer may be achieved by the use of u-type doping within this layer. Up to half of the InGaAsP layer is doped leaving the remainder with the original doping profile which creates separate potential wells for electrons and holes in different parts of the InGaAsP layer. To achieve the required separation, the region of the i-InGaAsP nearest the p-InP region is n-type doped, such doping being in the range 10¹⁷-10¹⁸ is cm⁻³, leaving the remainder un-doped. FIG. 6 shows the resulting band structure, taking account of band bending.

The resulting structure is a p⁺-n-i-n⁺ system. FIG. 7 shows schematically the structure where region 51 is p-doped InP, region 52 is n-doped InGaAsP, region 53 is intrinsic InGaAsP (i-InGaAsP) and region 54 is n-doped InP. The junction between the p-InP and the n-doped InGaAsP is 55, the junction between the n-doped InGaAsP and the i-InGaAsP is 56 and the junction between the i-InGaAsP and the n-IaP is 57. The result will be even more pronounced if the remaining part of the i-region 53 is p-doped, such doping being in the range 10¹⁵-10¹⁷ cm⁻³. However the doping has to be moderate to avoid increases in the optical losses mentioned above. This system is formally similar to a two terminal p-n-p-n Shockley diode, as shown in FIG. 8.

The structure embodied in the present invention is a Shockley heterodiode since there is an external p⁺-n heterojunction on the left side of the structure and an external i-n⁺ heterojunction on the right side of the structure. The centre n-i (or n-p) junction is a homojunction.

It is well known for a Shockley diode that for a positive anode and negative cathode voltage in the forward blocking regime the two external junctions are forward-biased and operate as effective emitters for electrons and holes, respectively, while the centre junction is reverse-biased. The electric field at the centre junction tries to separate the injected electrons and holes. Consequently the resulting current flowing through the structure remains very small and at the same time the density of injected electrons and holes is high.

FIG. 6 shows the energy band profile at thermodynamic equilibrium for the structure proposed. Shown are the two main effects of the modulation of the doping profile in the i-InGaAsP:
(a) The actual barrier for electrons at the (p-InP)-(n-InGaAsP)-heterojunction increases; and
(b) There is a potential well 41 for electrons in the n-doped region of the InGaAsP layer and a potential well 42 for holes in the undoped region of this layer.

The injected electrons will occupy the potential well 41 as shown by 43 and the injected holes will occupy the potential well 42 as shown by 44. This results in spatial separation of the electrons and holes. The carriers are not completely separated due to the relatively shallow nature of the potential wells 41 and 42.

When an external direct bias is applied during forward blocking, the reverse bias of the centre junction 56 is increased and the depth of the potential wells and the electric field strength at the junction will be also increased. This will lead to additional separation of the electrons and holes in InGaAsP layer and to suppression of the Auger recombination in this layer.

The electron leakage current over the heterojunction from the i-region is approximately an exponential function of the heterobarrier height. In order to decrease the leakage current it is necessary to increase the potential barrier for the electrons.

A further increase in barrier height maybe obtained by increasing the doping level in the p-region then the new Fermi level E_{Fp} in the p-region will lie closer to the valence band edge than in the case shown in FIG. 5. There is an additional Fermi level shift ΔE_{F}, as it shown in FIG. 9. As a result of this shift the new energy band profile will have an additional difference between the band energy in the p-region and in the i-region. The actual barrier height which is seen by the electrons on the i-p-heterobarrier is approximately equal ΔE_{C}≈ΔE_{C}*+ΔE_{F}. In principle, this means that at very high level of p-doping the heterobarrier height may be close to the bandgap difference between E_{g}^{InP} and E_{g}^{InGaAsP} instead of the conduction bands offset.

However such an increase in the p-doping level will result in increase of the optical losses due to the hole intervalence band absorption. This problem can be avoided if the high level doping profile will stop some distance away from the p-i-heterojunction.

Another way to increase the electron and the hole separation is to use the delta-doping. Two adjacent delta-doped layers, n-type doped layer on the left side and the p-type doped layer on the right side of the central junction, as shown in FIG. 14, will modify the potential barrier shape and create an additional built-in electric field located at the centre of the junction due to additional Fermi level alignment in the delta-doped regions, as shown in FIG. 15. The built-in field has such direction that it will push the electrons and holes in opposite directions further away from the junction

An alternative method for increasing the barrier for electrons on the (p-InP)-(i-InGaAsP)-heterojunction is to insert another material (a blocking layer) on the p-side between the above two materials. The appropriate candidate should increase the barrier for the electrons only, but not for the holes, in order to maintain the same injection level for the hole current This material should also be lattice matched to InP and InGaAsP.

Inspection of Table 1 shows that an appropriate material could be for example, InAlAs. It also may be InAlAsP as well. FIG. 10 shows the energy band profile of the structure before incorporation of the blocking layer, and FIG. 11 corresponds to the case when the InAlAs layer is inserted. The two diagrams have not included the effects of band bending for simplicity. It can be seen that insertion of the blocking layer provides an additional barrier for the electrons of about 0.2 eV and there would be no additional barrier for the holes. This will have the effect of decreasing of the electron leakage current but it will not effect the hole injection current.

Combining the two aspects of our invention achieves maximum tuning efficiency. The introduction of an increased barrier height will decrease the electron leakage current over the heterojunction from the i-region and thus increase the carrier density in the i-region. The modulation of the bandgap in the i-region will reduce the non-radiative recombinations by suppressing the Auger recombinations.

FIG. 12 shows the resulting band structure when the two aspects of our invention are combined. FIG. 13 shows the resulting band structure when a section of i-region is p-doped to enhance the separation of the carriers.

A device embodying one or more aspects of the invention may give increased wavelength tuning range. Due to the reduction of the tuning current, there will be a considerable decrease in heating of the device, which in turn will improve thermal stability and increase the tuning speed of the laser diode. The reduced tuning current also leads to less free carrier absorption, which in turn leads to a decrease in the output power non-uniformity.

1. A tuneable laser having a timing section comprising a homojunction structure that modifies the band structure to approximate that found in a type IT superlattice.

2. A tuneable laser having a tuning section comprising a homojunction structure comprising p and i layers, wherein up to half of the i layer is doped leaving the remainder with the original intrinsic state, so as to create separate potential wells for electrons and holes in different parts of the i layer.

3. The tuneable laser as claimed claim 2, wherein the region of the i layer nearest the p layer region is n-type doped, leaving the remainder undoped, to create a potential well for electrons in the n doped region of the i layer and a potential well for holes in the undoped region of this layer.

4. A tuneable laser having a tuning section comprises p and i layers, wherein the region of the i layer nearest the p layer is n˜type doped, with the remainder of the region being p-doped, so as to create separate potential wells for electrons and holes in different parts of the i layers.

5. The tuneable laser according to claim 2, wherein the p layer is of InP.

6. The tuneable laser according to claim 2, wherein the i layer is InGaAsP.

7. The tuneable laser according to claim 2, wherein the homojunction structure modifies the band structure to approximate that found in a type n superlattice.

8. A tuneable laser having a tuning section including a heterojunction comprising a blocking layer between the two materials thereof on the p-side, so as to increase the barrier for the electrons only, but not for the holes, while maintaining the same injection level for the electron and hole current.

9. The tuneable laser as claimed in claim 8, wherein insertion of the blocking layer provides an additional barrier for the electrons of about 0.2 eV and substantially no additional barrier for the holes.

10. The tuneable laser as claimed in claim 8, wherein the heterojunction is a (p-InP)-(i-InGaAsP)-structure_{>} and the material of the blocking layer is lattice matched thereto.

11. The tuneable laser as claimed in claim 10, wherein the blocking layer comprises InAlAs.

12. The tuneable laser as claimed in claim 10, wherein the blocking layer comprises InAlAsR

13. The tuneable laser as claimed in claim 8, further comprising two delta-doped layers, one on each side of and adjacent to a central junction,

14. (cancelled)
